(19) United States
(12) Patent Application Publication
(10) Pub. No.: US 2018/0252755 A1
(43) Pub. Date: Sep. 6, 2018

(54) METHOD OF PROCESSING S-PARAMETER TO ANALYZE TRANSIENT PHENOMENA

(71) Applicants: Jae Yong Cho, Gyeonggi-do (KR); HUWIN CO., LTD., Gyeonggi-do (KR)

(72) Inventors: Jae Yong Cho, Gyeonggi-do (KR); Seungil Jeung, Gyeonggi-do (KR)

(21) Appl. No.: 15/847,275

(22) Filed: Dec. 19, 2017

(30) Foreign Application Priority Data
Mar. 2, 2017 (KR) 10-2017-0027242

(51) Int. Cl. G01R 27/28

(52) U.S. Cl. CPC G01R 27/28

(57) ABSTRACT

Disclosed is a method of processing an S-parameter to analyze transient phenomena in a passive network, the method including: generating an extrapolation function related to a real part of a measured S-parameter signal; generating an expanded S-parameter signal by the extrapolation function; and setting an optimum degree and an optimum expansion frequency of the expanded S-parameter signal. Thus, the extrapolation function where continuity from the real part of the measured S-parameter signal is ensured is used such that causality in an impulse response of the expanded S-parameter signal can be maintained without problems.

### CROSS REFERENCE TO RELATED APPLICATION

The present application claims priority to Korean Patent Application 10-2017-0027242, filed Mar. 2, 2017, the entire contents of which is incorporated herein for all purposes by this reference.

### BACKGROUND OF THE INVENTION

### Field of the Invention

The present invention relates generally to a method of processing an S-parameter to analyze transient phenomena. More particularly, the present invention relates to a method of processing an S-parameter to analyze transient phenomena by using the S-parameter.

### Description of the Related Art

In analyzing transient phenomena of a passive network by using an S-parameter, there is a method of transforming an S-parameter into an equivalent circuit to perform a circuit simulation.

Analyzing of the transient phenomena by transforming the S-parameter into the equivalent circuit and performing a simulation can be used for an S-parameter having a limited measurement bandwidth (BW), but is disadvantageous in that the transformation process into the equivalent circuit is complex.

In the meantime, there is a method of analyzing transient phenomena by transforming an S-parameter into an impulse response and performing convolution calculation thereon with an input signal. The method is advantageous in that the S-parameter can be simply transformed into the impulse response through inverse fast Fourier transform (IFFT).

However, the method is problematic in that in the case of the S-parameter having the limited measurement bandwidth, a transformation error occurs due to a causality problem as shown in FIG. 1. Thus, there is a need for a method of preventing the causality problem in the S-parameter having the limited measurement bandwidth.

The foregoing is intended merely to aid in the understanding of the background of the present invention, and is not intended to mean that the present invention falls within the purview of the related art that is already known to those skilled in the art.

### Document of Related Art

(Patent Document 1) U.S. Patent Application Publication No. 2008-0281893.

### SUMMARY OF THE INVENTION

Accordingly, the present invention has been made keeping in mind the above problems occurring in the related art, and the present invention is intended to propose a method of processing an S-parameter to analyze transient phenomena, the method expanding an S-parameter signal to transform the S-parameter having a limited measurement bandwidth into an impulse response through inverse fast Fourier transform without a causality problem.

In order to achieve the above object, according to one aspect of the present invention, there is provided a method of processing an S-parameter to analyze transient phenomena in a passive network, the method including: generating an extrapolation function related to a real part of a measured S-parameter signal; generating an expanded S-parameter signal by the extrapolation function; and setting an optimum degree and an optimum expansion frequency of the expanded S-parameter signal.

At the generating of the extrapolation function related to the real part of the measured S-parameter signal, the extrapolation function may be generated to continue at a maximum frequency point of the real part of the measured S-parameter signal.

After the generating of the extrapolation function related to the real part of the measured S-parameter signal, the method may further include: verifying whether or not continuity between the real part of the measured S-parameter signal and the generated extrapolation function is ensured; generating a 2n-th degree polynomial function by using the extrapolation function; and calculating a coefficient of the extrapolation function.

The verifying of whether or not continuity between the real part of the measured S-parameter signal and the generated extrapolation function is ensured may be performed by formulas

$${F}_{Rm} ( {f}_{max} ) = {F}_{Re} ( {f}_{max} ) = p$$

$$\frac{{dF}_{Rm} ( {f}_{max} )}{df} = \frac{{dF}_{Re} ( {f}_{max} )}{df} = q$$

(here, F_{Rm} (fₘₐₓ) is a function of the real part of the measured S-parameter signal, F_{Re} (fₘₐₓ) is the extrapolation function related to the real part of the S-parameter signal, and fₘₐₓ is a maximum frequency).

At the generating of the 2n-th degree polynomial function by using the extrapolation function, an even function may be generated by using the extrapolation function that is generated at the generating of the extrapolation function related to the real part of the measured S-parameter signal, thereby generating the 2n-th degree polynomial function.

The 2n-th degree polynomial function that is generated at the generating of the 2n-th degree polynomial function by using the extrapolation function may be indicated as a formula

$$F ( f ) = {\sum }_{k = 0}^{n} {a}_{k} \cdot {f}^{2 k}$$

by shifting a reference point of the extrapolation function to zero (here, F(f) is the 2n-th degree polynomial function, aₖ is a coefficient of the 2n-th degree polynomial function, and f is a frequency).

The 2n-th degree polynomial function that is generated at the generating of the 2n-th degree polynomial function by using the extrapolation function may be indicated as a following formula, and the calculating of the coefficient of the extrapolation function may be performed from the following formula

$${F}_{Re} ( f ) = {\sum }_{k = 2}^{n} {a}_{k} \{ {( f - {f}_{ebw} - {f}_{max} )}^{2 k} - k \cdot {f}_{ebw}^{2 ( k - 1 )} \cdot {( f - {f}_{ebw} - {f}_{max} )}^{2} + ( k - 1 ) \cdot {f}_{ebw}^{2 k} \} - \frac{q}{2 {f}_{ebw}} {( f - {f}_{ebw} - {f}_{max} )}^{2} + \frac{q \cdot {f}_{ebw}}{2} + p$$

(here, F_{Re} (f) is the extrapolation function related to the S-parameter signal, aₖ is a coefficient of the 2n-th degree polynomial function, f is a frequency, f_{ebw} is fₑₓₚ−fₘₐₓ that is a frequency range where the extrapolation function is formed, fₑₓₚ is a maximum frequency of the extrapolation function, fₘₐₓ is a maximum frequency of the real part of the measured S-parameter signal, p is a maximum value at a maximum frequency of the 2n-th degree polynomial function, and q is a value obtained by differentiating p).

At the calculating of the coefficient of the extrapolation function, a set of aₖ may be calculated as [A].

The generating of the expanded S-parameter signal by the extrapolation function may include: generating the extrapolation function related to the S-parameter signal by using the measured S-parameter signal, an expansion frequency, and a function degree; calculating the real part of the S-parameter signal of which a frequency is expanded by the extrapolation function; performing Hilbert transform on the real part of the S-parameter signal of which the frequency is expanded by the extrapolation function, and obtaining a negative value thereof so as to calculate an imaginary number part of the real part of the S-parameter signal of which the frequency is expanded; and adding the calculated real part of the S-parameter signal of which the frequency is expanded by the extrapolation function and the imaginary number part of the real part of the S-parameter signal of which the frequency is expanded, whereby a frequency-expanded S-parameter signal where causality is ensured is generated.

At the setting of the optimum degree and the optimum expansion frequency of the expanded S-parameter signal, an arbitrary degree 2n and an arbitrary expansion frequency fₑₓₚ at which the expanded S-parameter signal converges to zero may be set as the optimum degree and the optimum expansion frequency.

According to an embodiment of the present invention, in the method of processing the S-parameter to analyze transient phenomena, an expansion function is added to an S-parameter and inverse fast Fourier transform is performed thereon such that transform into an impulse response is performed, whereby an analysis of transient phenomena can be performed without a complex transformation process into an equivalent circuit. Also, in analyzing transient phenomena from the S-parameter having the limited measurement bandwidth, a causality problem can be prevented.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a view illustrating a case in which a causality problem occurs when an S-parameter having a limited measurement bandwidth is transformed into an impulse response according to a conventional method;

FIG. 2 is a flowchart illustrating a method of processing an S-parameter to analyze transient phenomena according to an embodiment of the present invention;

FIG. 3 is a view illustrating an S-parameter measurement signal and an extrapolation function related thereto to which the method of processing an S-parameter to analyze transient phenomena according to an embodiment of the present invention is applied;

FIGS. 4A-C separately illustrate an S-parameter measurement signal and an extrapolation function related thereto to which the method of processing an S-parameter to analyze transient phenomena according to an embodiment of the present invention is applied;

FIG. 5 is a view illustrating an S-parameter measurement signal and an extrapolation function related thereto, and a signal generated by laterally inverting the S-parameter measurement signal and the extrapolation function to which the method of processing an S-parameter to analyze transient phenomena according to an embodiment of the present invention is applied;

FIG. 6 is a view illustrating the signal in FIG. 5 of which a reference point is shifted;

FIG. 7 is a flowchart illustrating in detail generating an expanded S-parameter signal by an extrapolation function in the method of processing an S-parameter to analyze transient phenomena according to an embodiment of the present invention;

FIGS. 8A to 8C are views illustrating convergence types of an extrapolation function related to an S-parameter measurement signal to which the method of processing an S-parameter to analyze transient phenomena according to an embodiment of the present invention is applied;

FIG. 9 is a flowchart illustrating in detail setting an optimum degree and an optimum expansion frequency in the method of processing an S-parameter to analyze transient phenomena according to an embodiment of the present invention; and

FIGS. 10A and 10B are views respectively illustrating a network structure to which the method of processing an S-parameter to analyze transient phenomena is applied and a graph illustrating an impulse response in consequence of applying the method according to an embodiment of the present invention.

### DETAILED DESCRIPTION OF THE INVENTION

Hereinbelow, exemplary embodiments of the present invention will be described in detail with reference to the accompanying drawings such that the present invention can be easily embodied by one of ordinary skill in the art to which this invention belongs. However, the embodiments may be variously changed and the scope and spirit of the present invention are not limited to the embodiments described hereinbelow. In order to clearly explain the present disclosure, portions that are not related to the present disclosure are omitted in the drawings, and like reference numerals designate like elements throughout the specification.

A method of processing an S-parameter to analyze transient phenomena according to an embodiment of the present invention will be described in detail with reference to the accompanying drawings.

In the description of the specification, a subject performing an operation may be a processor measuring and processing an S-parameter to analyze transient phenomena of a passive network. As another example, the subject may be a recording medium in which a program enabling measuring and processing processes to be executed is recorded or a device including the recording medium.

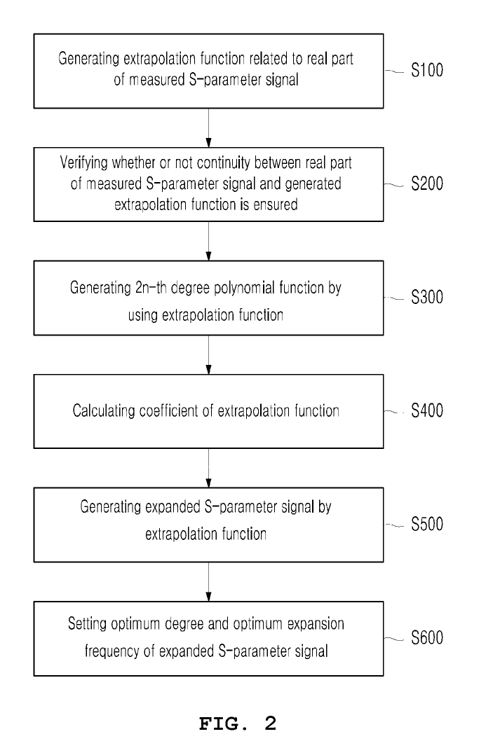

First, as shown in FIG. 2, a method of processing an S-parameter to analyze transient phenomena according to an embodiment of the present invention may include: generating an extrapolation function related to a real part of a measured S-parameter signal at step S100; verifying whether or not continuity between the real part of the measured S-parameter signal and the generated extrapolation function is ensured at step S200; generating a 2n-th degree polynomial function by using the extrapolation function at step S300; calculating a coefficient of the extrapolation function at step S400; generating an expanded S-parameter signal by the extrapolation function at step S500; and setting an optimum degree and an optimum expansion frequency of the expanded S-parameter signal at step S600.

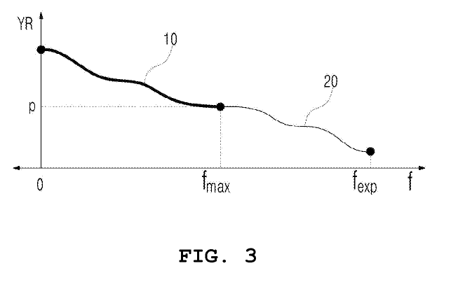

Here, at step S100, as shown in FIG. 3, a real part 10 of the measured S-parameter signal is a signal obtained by measuring the linear scale for a frequency (f) by y_{R}. An extrapolation function 20 related to the real part 10 of the measured S-parameter signal is a signal continuing from a maximum frequency point of the real part 10 of the S-parameter signal.

The extrapolation function 20 related to the real part 10 of the measured S-parameter signal also has a linear scale for a frequency as the y_{R} value.

At step S100, the real part 10 of the measured S-parameter signal has the maximum frequency fₘₐₓ, and the extrapolation function 20 related to the real part 10 of the S-parameter has the maximum frequency fₑₓₚ as starting from fₘₐₓ that is the maximum frequency of the real part 10 of the S-parameter signal.

As described above, as generating the extrapolation function 20 related to the real part 10 of the measured S-parameter signal, the maximum frequency of the measured S-parameter signal expands from fₘₐₓ to fₑₓₚ.

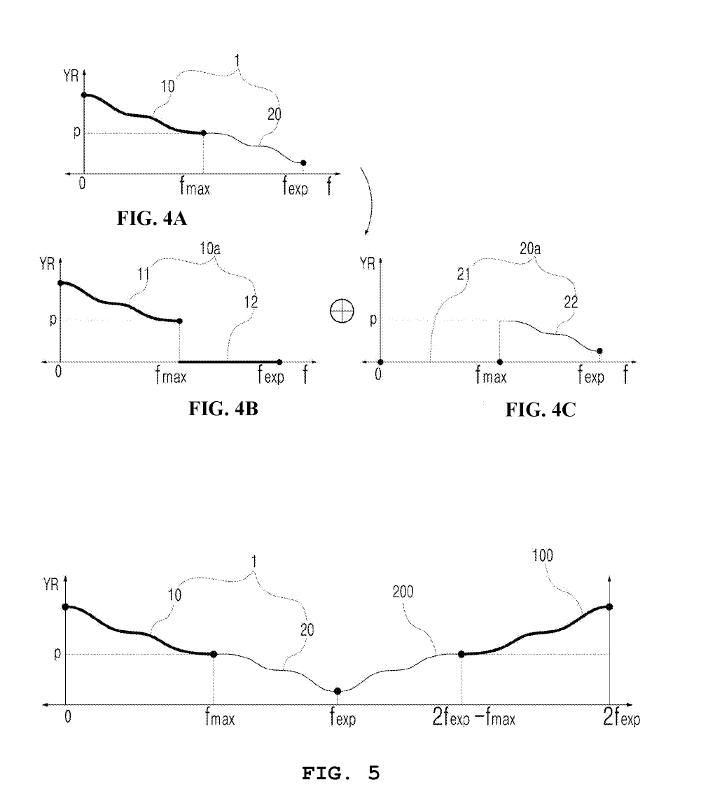

Here, the expanded signal by the extrapolation function 20 in FIG. 3 may be divided as shown in FIGS. 4(a)-(c). Referring to FIGS. 4(a)-(c), the expanded signal 1 having the real part 10 of the measured S-parameter signal and the extrapolation function 20 related thereto continues from a frequency of zero to fₑₓₚ as shown in FIG. 4(a), but may be regarded as a combination of FIGS. 4(b) and 4(c).

Referring to FIGS. 4(b) and 4(c), the expanded signal 1 may be divided into the real part 10 of the measured S-parameter signal and the extrapolation function 20 related thereto. The expanded signal 1 and the signals 10 and 20 composing the expanded signal 1 are indicated as the following formula 1.

$${y}_{R} = {F}_{t} ( f ) = \{ \begin{matrix}{F}_{Rm} ( f ) , 0 \leq f \leq {f}_{max} \\ {F}_{Re} ( f ) , {f}_{max} < f \leq {f}_{exp} \\ 0 , f > {f}_{exp} or f < {f}_{max}\end{matrix} \\ {y}_{R} = \{ \begin{matrix}{F}_{Rm} ( f ) , 0 \leq f \leq {f}_{max} \\ 0 , f > {f}_{max}\end{matrix} \\ {y}_{R} = \{ \begin{matrix}{F}_{Re} ( f ) , {f}_{max} < f \leq {f}_{exp} \\ 0 , f > {f}_{exp} or f < {f}_{max}\end{matrix} \qquad [ Formula 1 ]$$

In formula 1, like FIG. 4(a), the expanded signal 1 y_{R} is Fₜ(f) that is a function of frequency in the time domain, and may be indicated as a combination of a function F_{Rm}(f) when a frequency (f) range is equal to or greater than zero and is equal to less than fₘₐₓ, the extrapolation function F_{Re}(f) when a frequency range exceeds fₘₐₓ and is equal to less than fₑₓₚ, and a function of which a value is zero when a frequency range exceeds fₑₓₚ or less fₘₐₓ.

Here, a function indicating the extrapolation function related to the real part of the S-parameter signal with respect to a frequency is indicated as F_{Re}(f). A function for the real part of the measured S-parameter signal is indicated as F_{Rm}(f).

As shown in FIG. 4B, a real part 10a of the measured S-parameter signal may be indicated as a combination of a first signal portion 11 and a second signal portion. The signal y_{R} of the real part 10a of the measured S-parameter signal may be indicated as a combination of a function F_{Rm}(f) when the frequency is equal to or greater than zero and is equal to or less than fₘₐₓ and a function of which a value is zero when the frequency exceeds fₘₐₓ as shown in formula 1.

Here, as shown in FIG. 4C, the extrapolation function 20a related to the real part 10 of the measured S-parameter signal may be indicated as a combination of a third signal portion 21 and a fourth signal portion 22. The signal y_{R} of the extrapolation function 20a may be indicated as a combination of a function F_{Re}(f) when the frequency exceeds fₘₐₓ and is equal to or less than fₑₓₚ and a function of which a value is zero when the frequency exceeds fₑₓₚ as shown in formula 1.

As described above with reference to FIG. 4 and formula 1, the expanded signal 1 y_{R} may be regarded as a combination of the real part 10a of the measured S-parameter signal divided into the first signal portion 11 and the second signal portion 12, and the extrapolation function 20a divided into the third signal portion 21 and the fourth signal portion 22.

Referring to FIG. 2 again, in the method of processing the S-parameter to analyze transient phenomena according to an embodiment of the present invention, whether or not continuity between the real part of the measured S-parameter signal and the generated extrapolation function is ensured is verified at step S200.

At step S200, whether or not the real part 10 of the measured S-parameter signal continues to the extrapolation function 20 at fₘₐₓ in FIG. 3 is verified. In the expression of the expanded function 1 in formula 1, when the value of F_{Rm}(f) at fₘₐₓ and the value of F_{Re}(f) at fₘₐₓ are all p, it indicates that continuity is ensured.

That is, whether or not continuity between the real part 10 of the S-parameter signal and the extrapolation function 20 is ensured may be verified by the following formula 2.

$${F}_{Rm} ( {f}_{max} ) = {F}_{Re} ( {f}_{max} ) = p \\ \frac{{dF}_{Rm} ( {f}_{max} )}{df} = \frac{{dF}_{Re} ( {f}_{max} )}{df} = q \qquad [ Formula 2 ]$$

In formula 2, values obtained by respectively differentiating the value of F_{Rm}(f) at fₘₐₓ and the value of F_{Re}(f) at fₘₐₓ with respect to frequency are equally set to q such that continuity between the real part 10 of the S-parameter signal and the extrapolation function 20 is ensured.

Here, formula 2 is used to set the fₘₐₓ point as a resonance point so as to enable differential values of all points except the resonance point to continue in the S-parameter.

At step S300, the 2n-th degree polynomial function is generated by using the extrapolation function, and here, an even function is generated by using the extrapolation function shown in FIG. 3 to generate the 2n-th degree polynomial function.

Specifically, in the expanded function 1 of FIG. 3, the real part 10 of the S-parameter signal is obtained by performing Fourier transform (FT) to the frequency band on the S-parameter in the time domain such that the S-parameter is bisymmetrical with respect to the center point Fₛ/2 of the sampling frequency Fₛ. In the S-parameter of the frequency band on which Fourier transform is performed in a bisymmetrical form, the signal only in a range of zero to fₘₐₓ is used as the real part 10 of the S-parameter signal as shown in FIG. 3.

However, when generating the 2n-th degree polynomial function by laterally inverting the extrapolation function 20 in a form of an even function at step S300, the extrapolation function 20 continues to a laterally inverted extrapolation function 200 obtained by laterally inverting the extrapolation function 20 as shown in FIG. 5. Here, the S-parameter of the frequency band in a bisymmetrical form, the laterally inverted extrapolation function 200 continues to a signal 100 in a range of 2fₑₓₚ_31 fₘₐₓ to 2fₑₓₚ.

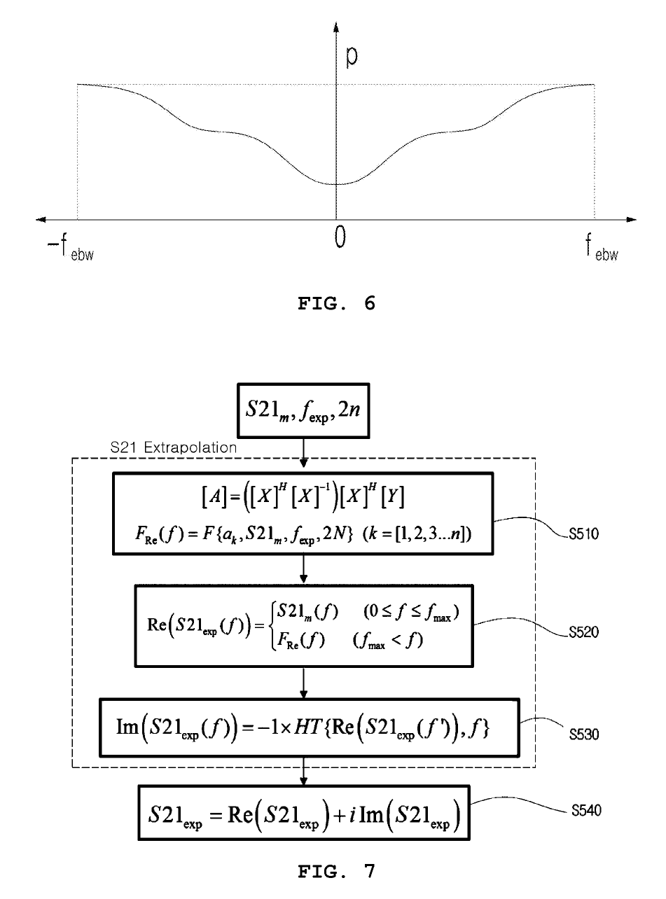

Consequently, at step S300, the 2n-th degree polynomial function in a form where the extrapolation function 20 continues to the laterally inverted extrapolation function 200 is generated as shown in FIG. 6.

The 2n-th degree polynomial function shown in FIG. 6 is obtained by shifting a reference point of the 2n-th degree polynomial function in a section from fₘₐₓ to 2fₑₓₚ−fₘₐₓ in FIG. 5 to zero. A range of the extrapolation function 20 from fₘₐₓ to fₑₓₚ is replaced with f_{ebw}, and the axis is shifted to zero as a reference point, whereby a 2n-th degree polynomial function that is bisymmetrical in a range from −f_{ebw} to f_{ebw} and has the maximum value of p is obtained in a form of an even function as shown in FIG. 6.

$$\begin{matrix}F ( f ) = {\sum }_{k = 0}^{n} {a}_{k} \cdot {f}^{2 k} & [ Formula 3 ] \\ F ( - {f}_{ebw} ) = {\sum }_{k = 0}^{n} {a}_{k} \cdot {f}_{ebw}^{2 k} = {\sum }_{k = 1}^{n} {a}_{k} \cdot {f}_{ebw}^{2 k} + {a}_{0} = p \\ {F}^{′} ( - {f}_{ebw} ) = \frac{dF ( - {f}_{ebw} )}{df} = q \\ {F}^{′} ( - {f}_{ebw} ) = - {\sum }_{k = 1}^{n} {a}_{k} \cdot 2 k \cdot {f}_{ebw}^{( 2 k - 1 )} = - {\sum }_{k = 2}^{n} {a}_{k} \cdot 2 k \cdot {f}_{ebw}^{( 2 k - 1 )} - {a}_{1} \cdot 2 \cdot {f}_{ebw} = q \\ {a}_{1} = \frac{{\sum }_{k = 2}^{n} {a}_{k} \cdot 2 k \cdot {f}_{ebw}^{( 2 k - 1 )} + q}{- 2 {f}_{ebw}} & [ Formula 4 ]\end{matrix}$$

In formula 3, the 2n-th degree polynomial function as shown in FIG. 6 is designated by F(f), and a coefficient of the 2n-th degree polynomial function is designated by aₖ.

Formula 4 indicates that when the frequency of the 2n-th degree polynomial function is −f_{ebw}, the value is p. When substituting the frequency −f_{ebw} for formula 3 in a case of k=0, a₀ is obtained.

Here, assuming that a value obtained by differentiating the 2n-th degree polynomial function with respect to frequency is q, when differentiating the 2n-th degree polynomial function in a case where the frequency is −f_{ebw}, it is indicated as calculation of −a₁·2·f_{ebw} obtained when k is one and a sum function with k starting from two as shown in formula 4, whereby a₁ can be obtained.

Here, when differential equations that are the second equation and the third equation of formula 4 are substituted for the first equation of formula 4, it is indicated as formula 5. When the differential equations of formula 4 and formula 5 are substituted for the first equation of formula 4, it is indicated a formula 6.

$$\begin{matrix}{\sum }_{k = 2}^{n} {a}_{k} \cdot {f}_{ebw}^{2 k} + \frac{{\sum }_{k = 2}^{n} {a}_{k} \cdot 2 k \cdot {f}_{ebw}^{( 2 k + 1 )} + q}{- 2 {f}_{ebw}} \cdot {f}_{ebw}^{2} + {a}_{0} = {\sum }_{k = 2}^{n} {a}_{k} \cdot {f}_{ebw}^{2 k} - {\sum }_{k = 2}^{n} {a}_{k} \cdot k \cdot {f}_{ebw}^{2 k} - \frac{q \cdot {f}_{ebw}}{2} + {a}_{0} = p \\ {a}_{0} = {\sum }_{k = 2}^{n} {a}_{k} \cdot ( k - 1 ) \cdot {f}_{ebw}^{2 k} + \frac{q \cdot {f}_{ebw}}{2} + p & [ Formula 5 ] \\ F ( f ) = {\sum }_{k = 0}^{n} {a}_{k} \cdot {f}^{2 k} = {\sum }_{k = 2}^{n} {a}_{k} \cdot {f}^{2 k} + \frac{{\sum }_{k = 2}^{n} {a}_{k} \cdot 2 k \cdot {f}_{ebw}^{( 2 k + 1 )} + q}{- 2 {f}_{ebw }} \cdot {f}_{ebw}^{2} + {\sum }_{k = 2}^{n} {a}_{k} \cdot ( k - 1 ) \cdot {f}_{ebw}^{2 k} + \frac{q \cdot {f}_{ebw}}{2} + p = {\sum }_{k = 2}^{n} {a}_{k} \{ {f}^{2 k} - k \cdot {f}_{ebw}^{2 ( k + 1 )} \cdot {f}^{2} + ( k - 1 ) \cdot {f}_{ebw}^{2 k} \} - \frac{q}{2 {f}_{ebw}} {f}^{2} + \frac{q \cdot {f}_{ebw}}{2} + p & [ Formula 6 ]\end{matrix}$$

Formula 6 indicates the 2n-th degree polynomial function in a symmetrical form with respect to a point where the frequency is zero as shown in FIG. 6. When the axis of the center frequency is shifted to fₑₓₚ, which is the middle position of frequency from fₘₐₓ to 2 fₑₓₚ−fₘₐₓ, namely, the original position of the 2n-th degree polynomial function in FIG. 5, the 2n-th degree polynomial function is famed as shown in FIG. 6. Here, the 2n-th degree polynomial function where the center frequency is fₑₓₚ is indicated as formula 7.

$${F}_{Re} ( f ) = {\sum }_{k = 2}^{n} {a}_{k} \{ {( f - {f}_{ebw} - {f}_{max} )}^{2 k} - k \cdot {f}_{ebw}^{2 ( k - 1 )} \cdot {( f - {f}_{ebw} - {f}_{max} )}^{2} + ( k - 1 ) \cdot {f}_{ebw}^{2 k} \} - \frac{q}{2 {f}_{ebw}} {( f - {f}_{ebw} - {f}_{max} )}^{2} + \frac{q \cdot {f}_{ebw}}{2} + p \qquad [ Formula 7 ]$$

Referring to FIG. 2 again, at step S400, a coefficient aₖ is calculated from the 2n-th degree polynomial function of formula 8. Here, from formulas 8 and 9, whether or not the real part of the measured S-parameter signal satisfies a causality condition may be verified.

$$\begin{matrix}HT \{ X ( f ) , {f}_{i} \} = \frac{1}{π} P {\int }_{- ∞}^{∞} \frac{X ( f )}{{f}_{i} - f} df & [ Formula 8 ] \\ {F}_{R} ( {f}_{i} ) = HT \{ {F}_{X} ( f ) , {f}_{i} \} = \frac{1}{π} P {\int }_{- ∞}^{∞} \frac{{F}_{X} ( f )}{{f}_{i} - f} df \\ {F}_{X} ( {f}_{i} ) = - HT \{ {F}_{R} ( f ) , {f}_{i} \} = - \frac{1}{π} P {\int }_{- ∞}^{∞} \frac{{F}_{R} ( f )}{{f}_{i} - f} df & [ Formula 9 ]\end{matrix}$$

Formula 8 indicates Hilbert transform (HT). When performing Hilbert transform on an integration target function X(f) and an input value fᵢ, it indicated as the right-side equation. Here, P is a Cauchy principal value.

In formula 9, Hilbert transform is performed on F_{R}(f) and F_{X}(f) with reference to formula 8. Here, F_{R}(f) is a function indicating a real number part of the S-parameter signal, and F_{X}(f) is a function indicating an imaginary number part of the S-parameter signal.

Here, in formula 9, F_{R}(f) is equal to (HT{F_{X}(f), fᵢ}) that is a result obtained by performing Hilbert transform on F_{X}(f) and ω, and F_{X}(f) is equal to a negative value of a result obtained by performing Hilbert transform on F_{R}(f) and fᵢ. Therefore, F_{R}(f) and F_{X}(f) satisfy a causality condition in the time domain, and thus Kramers-Kronig relations are satisfied.

Also, formula 9 where F_{R}(f) and F_{X}(f) satisfy a causality condition in the time domain is applied when a range of the measurement frequency is 0≤f<fₘₐₓ.

However, here, when the bandwidth of the real part of the measured S-parameter signal is limited, namely, when the maximum frequency fₘₐₓ is less than a bandwidth frequency f_{bw}, the function F_{Xm}(f) of the imaginary number part of the real part of the measured S-parameter signal is different from a negative value of the result obtained by performing Hilbert transform on the real part of the measured S-parameter signal.

This may be indicated as formula 10.

F_{X}_{ₘ}(fᵢ)≠−1×HT{F_{R}_{ₘ}(f),fᵢ}, (fₘₐₓ<f_{bw}) [Formula 10]

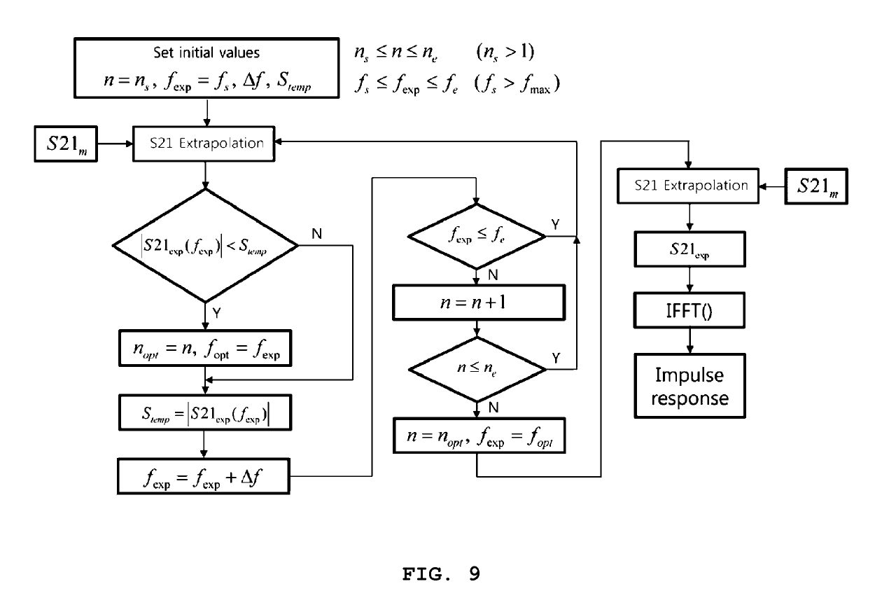

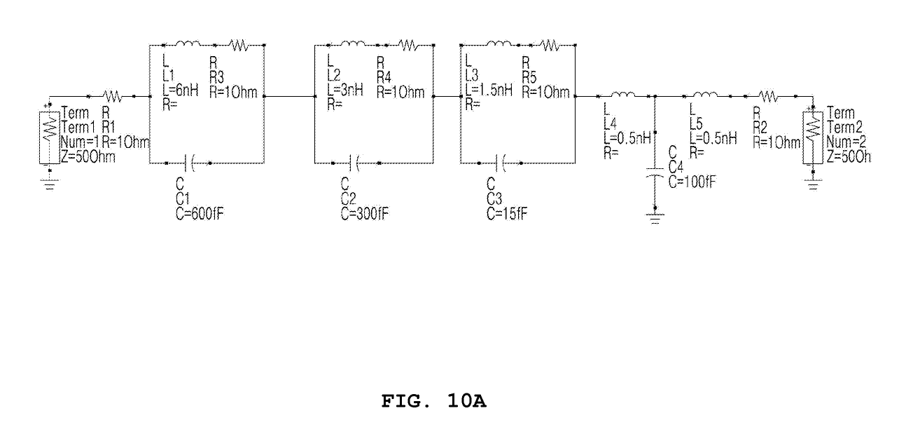

In formula 10, when the bandwidth of the real part of the measured S-parameter signal is limited, causality may not be ensured, and thus Kramers-Kronig relations may not established. However, the bandwidth of the real part of the measured S-parameter signal is greater than a response bandwidth of a network (f>f_{bw}), a causality condition is satisfied as shown in FIG. 9.

At step S400, the coefficient aₖ of the extrapolation function F_{R}(f) is calculated by organizing formula 11 as formula 12.

$$\begin{matrix}- 1 \times HT \{ ( {F}_{Rm} ( f ) + {F}_{Re} ( f ) ) , {f}_{i} \} = {F}_{Xm} ( {f}_{i} ) , ( where 0 \leq {f}_{i} \leq {f}_{max} ) & [ Formula 11 ] \\ \begin{matrix}{F}_{Xm} ( {f}_{i} ) = & - 1 \times HT \{ ( {F}_{Rm} ( f ) ) + ( {F}_{Re} ( f ) ) , {f}_{i} \} ( 0 \leq {f}_{i} \leq {f}_{max} ) \cdot \\ = & - HT \{ {F}_{Rm} ( f ) , {f}_{i} \} - HT \{ {F}_{Re} ( f ) , {f}_{i} \} \cdot \\ = & - 1 \times HT \{ {F}_{Rm} ( f ) , {f}_{i} \} \\ & - HT [ ( {\sum }_{k = 2}^{n} {a}_{k} \{ {( f - {f}_{ebw} - {f}_{max} )}^{2 k} - k \cdot {f}_{ebw}^{2 ( k + 1 )} \cdot {( f - {f}_{ebw} - {f}_{max} )}^{2} + ( k - 1 ) \cdot {f}_{ebw}^{2 k} \} \\ & - \frac{q}{2 {f}_{ebw}} {( f - {f}_{ebw} - {f}_{max} )}^{2} + \frac{q \cdot {f}_{ebw}}{2} + p ) , {f}_{i} ] \cdot \\ = & - 1 \times HT \{ {F}_{Rm} ( f ) , {f}_{i} \} \cdot \\ & - {\sum }_{k = 2}^{m} {a}_{k} \cdot HT \{ {( f - {f}_{ebw} - {f}_{max} )}^{2 k} - k \cdot {f}_{ebw}^{2 ( k - 1 )} \cdot {( f - {f}_{ebw} - {f}_{max} )}^{2} + ( k - 1 ) \cdot {f}_{ebw}^{2 k} ) , {f}_{i} \} \\ & - HT \{ ( - \frac{q}{2 {f}_{ebw}} {( f - {f}_{ebw} - {f}_{max} )}^{2} + \frac{q \cdot {f}_{ebw}}{2} + p ) , {f}_{i} \} \cdot \\ & {\sum }_{k = 2}^{n} {a}_{k} \cdot HT \{ ( {( f - {f}_{ebw} - {f}_{max} )}^{2 k} - k \cdot {f}_{ebw}^{2 ( k - 1 )} \cdot {( f - {f}_{ebw} - {f}_{max} )}^{2} + ( k - 1 ) \cdot {f}_{ebw}^{2 k} ) , {f}_{i} \} \cdot \\ = & - {F}_{Xm} ( {f}_{i} ) - HT \{ {F}_{Rm} ( f ) , {f}_{i} \} - HT \{ ( - \frac{q}{2 {f}_{0}} {( f - {f}_{ebw} - {f}_{max} )}^{2} + \frac{q \cdot {f}_{max}}{2} + p ) , {f}_{i} \} \cdot \end{matrix} \\ [ A ] = [ {a}_{2} {a}_{3} {a}_{4} ⋯ {a}_{N} ] \cdot \\ {s}_{k} ( {f}_{i} ) = HT \{ ( {( f - {f}_{ebw} - {f}_{max} )}^{2} - k \cdot {f}_{ebw}^{2 ( k - 1 )} \cdot {( f - {f}_{ebw} - {f}_{max} )}^{2} + ( k - 1 ) \cdot {f}_{ebw}^{2 k} ) , {f}_{i} \} \cdot \\ [ {s}_{k} ] = [ {s}_{k} ( {f}_{1} ) {s}_{k} ( {f}_{2} ) {s}_{k} ( {f}_{3} ) ⋯ {s}_{k} ( {f}_{M} ) ] , {f}_{M} = {f}_{max} \cdot \\ [ X ] = {[ {S}_{2} {S}_{3} {S}_{4} ⋯ {S}_{N} ]}^{T} \cdot \\ c ( {f}_{i} ) = - {F}_{Xm} ( {f}_{i} ) - HT \{ {F}_{Rm} ( f ) , {f}_{i} \} - HT \{ ( - \frac{q}{2 {f}_{0}} {( f - {f}_{ebw} - {f}_{max} )}^{2} + \frac{q \cdot {f}_{ebw}}{2} + p ) , {f}_{i} \} \cdot & [ Formula 12 ]\end{matrix}$$

As described above, [A] (a set of coefficients) multiplied by [X] (a set of frequency polynomials to which coefficients are applied) makes [Y] (which is a set of coefficients and frequency polynomials to which coefficients are not applied). This is indicated as [A][X]=[Y].

Here, n is a degree of a function, f_{M} is a measured frequency, f_{ebw} is an expansion range of a frequency, fₑₓₚ is an expansion frequency, and a range of a measurement frequency is equal to or greater than zero and less than fₘₐₓ.

Here, [A] a set of coefficients aₖ is derived by applying

[A]=([X]^{H}[X ]⁻¹) [X]^{H}[Y] [Formula 13]

As described above, after calculating coefficients of the extrapolation function, the expanded S-parameter signal by the extrapolation function is generated at step S500.

The step S500 will be described in detail with reference to FIG. 7. By using the measured S-parameter signal S21ₘ, the expansion frequency fₑₓₚ, and the function degree 2n, the extrapolation function F_{Re}(f) related to the S-parameter signal S21ₘ is generated at step S510.

Next, the real part (Re(S21ₑₓₚ(f)) of the S-parameter signal S21ₘ of which a frequency is expanded by the extrapolation function is calculated at step S520.

Next, in performing Hilbert transform on the real part (Re(S21ₑₓₚ(f)) of the S-parameter signal of which a frequency is expanded by the extrapolation function, the function F(f) and an input variable fᵢ are used.

Next, the real part (Re(S21ₑₓₚ(f)) of the S-parameter signal of which a frequency is expanded by the extrapolation function, which is calculated at steps S520 and S530 is added to an imaginary number part (iIm(S21ₑₓₚ)) obtained by multiplying i and the real part of the S-parameter signal of which a frequency is expanded, whereby a frequency-expanded S-parameter signal S21ₑₓₚ where causality is ensured is generated at step S540.

Last, the optimum degree and expansion frequency of the expanded S-parameter signal are set at step S600, since at an arbitrary degree 2n and an arbitrary expansion frequency S21ₑₓₚ may not converge to zero.

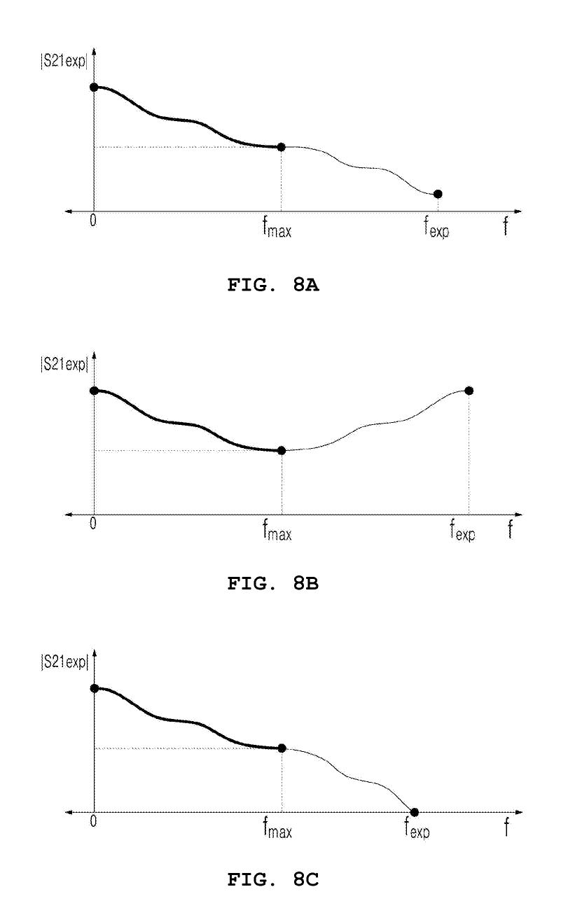

Referring to FIGS. 8A to 8C, this will be described in detail. As shown in FIG. 8A illustrating a graph of absolute value of S21ₑₓₚ with respect to frequency, the extrapolation function graph in a range of fₘₐₓ to fₑₓₚ converges in a direction of zero, but the absolute values from fₑₓₚ to S21ₑₓₚ are larger than zero.

As shown in FIG. 8B illustrating a graph of absolute values of S21ₑₓₚ with respect to frequency, the extrapolation function graph in a range of fₘₐₓ to fₑₓₚ f diverges rather than converges in a direction of zero.

Here, as shown in FIG. 8C illustrating a graphs of absolute values of S21ₑₓₚ with respect to frequency, the extrapolation function graph in a range of fₘₐₓ to fₑₓₚ converges in a direction of zero, and the absolute values from fₑₓₚ to S21ₑₓₚ converge to zero. Thus, the optimum degree n and the optimum expansion frequency fₑₓₚ providing the graph shape are set.

The n of the optimum degree 2n and the optimum expansion frequency fₑₓₚ are obtained through an algorithm of FIG. 9, and the impulse response is generated from the algorithm of FIG. 9.

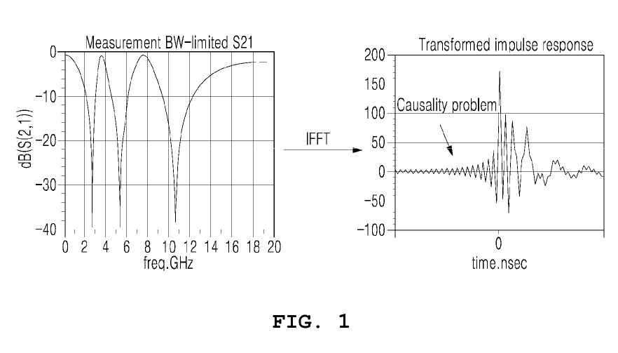

As described above with reference to FIGS. 1 to 9, according to the method of processing the S-parameter to analyze transient phenomena, the extrapolation function where continuity from the real part of the measured S-parameter signal is ensured is used such that causality in the impulse response of the expanded S-parameter signal can be maintained without problems.

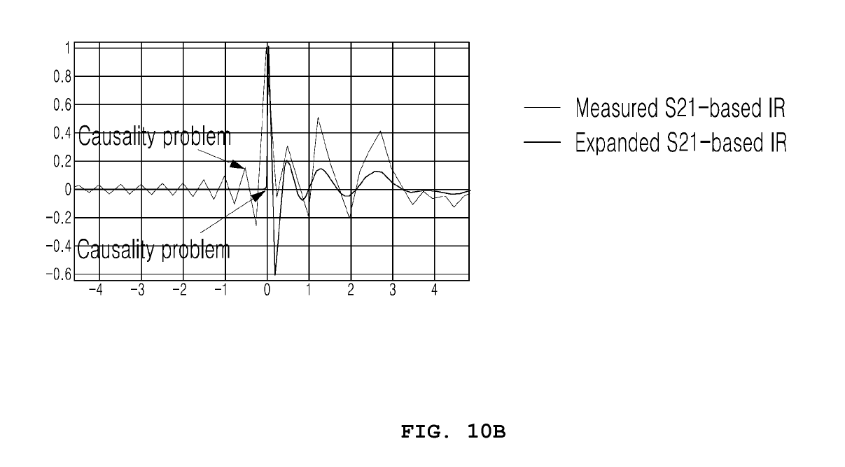

For example, when measuring an S-parameter in a network structure having a form shown in FIG. 10A and a frequency range of 0˜20 GHz, as shown in FIG. 10B, causality is maintained in the impulse response derived by performing IFFT on the expanded S-parameter measured in the relevant network, whereas causality error occurs in the impulse response derived by performing IFFT on the measured S-parameter.

Here, the impulse response shown in FIG. 10B is a signal to which the sixth degree function is applied.

Although embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A method of processing an S-parameter to analyze transient phenomena in a passive network, the method comprising:
generating an extrapolation function related to a real part of a measured S-parameter signal;
generating an expanded S-parameter signal by the extrapolation function; and
setting an optimum degree and an optimum expansion frequency of the expanded S-parameter signal.

2. The method according to claim 1, wherein at the generating of the extrapolation function related to the real part of the measured S-parameter signal, the extrapolation function is generated to continue at a maximum frequency point of the real part of the measured S-parameter signal.

3. The method according to claim 1, after the generating of the extrapolation function related to the real part of the measured S-parameter signal, further comprising:
verifying whether or not continuity between the real part of the measured S-parameter signal and the generated extrapolation function is ensured;
generating a 2n-th degree polynomial function by using the extrapolation function; and
calculating a coefficient of the extrapolation function.

4. The method according to claim 3, wherein the verifying of whether or not continuity between the real part of the measured S-parameter signal and the generated extrapolation function is ensured is performed by formulas
$${F}_{Rm} ( {f}_{max} ) = {F}_{Re} ( {f}_{max} ) = p$$
$$\frac{{dF}_{Rm} ( {f}_{max} )}{df} = \frac{{dF}_{Re} ( {f}_{max} )}{df} = q$$
(here, F_{Rm}(fₘₐₓ) is a function of the real part of the measured S-parameter signal, F_{Re}(fₘₐₓ) is the extrapolation function related to the real part of the S-parameter signal, and fₘₐₓ is a maximum frequency).

5. The method according to claim 3, wherein at the generating of the 2n-th degree polynomial function by using the extrapolation function, an even function is generated by using the extrapolation function that is generated at the generating of the extrapolation function related to the real part of the measured S-parameter signal, thereby generating the 2n-th degree polynomial function.

6. The method according to claim 3, wherein the 2n-th degree polynomial function that is generated at the generating of the 2n-th degree polynomial function by using the extrapolation function is indicated as a formula
$$F ( f ) = {\sum }_{k = 0}^{n} {a}_{k} \cdot {f}^{2 k}$$
by shifting a reference point of the extrapolation function to zero (here, F(f) is the 2n-th degree polynomial function, aₖ is a coefficient of the 2n-th degree polynomial function, and f is a frequency).

7. The method according to claim 3, wherein the 2n-th degree polynomial function that is generated at the generating of the 2n-th degree polynomial function by using the extrapolation function is indicated as a following formula, and the calculating of the coefficient of the extrapolation function is performed from the following formula
$${F}_{Re} ( f ) = {\sum }_{k = 2}^{n} {a}_{k} \{ {( f - {f}_{ebw} - {f}_{max} )}^{2 k} - k \cdot {f}_{ebw}^{2 ( k - 1 )} \cdot {( f - {f}_{ebw} - {f}_{max} )}^{2} + ( k - 1 ) \cdot {f}_{ebw}^{2 k} \} - \frac{q}{2 {f}_{ebw}} {( f - {f}_{ebw} - {f}_{max} )}^{2} + \frac{q \cdot {f}_{ebw}}{2} + p$$
(here, F_{Re}(f) is the extrapolation function related to the S-parameter signal, aₖ is a coefficient of the 2n-th degree polynomial function, f is a frequency, f_{ebw} is fₑₓₚ−fₘₐₓ that is a frequency range where the extrapolation function is formed, fₑₓₚ is a maximum frequency of the extrapolation function, fₘₐₓ is a maximum frequency of the real part of the measured S-parameter signal, p is a maximum value at a maximum frequency of the 2n-th degree polynomial function, and q is a value obtained by differentiating p).

8. The method according to claim 3, wherein at the calculating of the coefficient of the extrapolation function, a set of aₖ is calculated as [A].

9. The method according to claim 1, wherein the generating of the expanded S-parameter signal by the extrapolation function includes:
generating the extrapolation function related to the S-parameter signal by using the measured S-parameter signal, an expansion frequency, and a function degree;
calculating the real part of the S-parameter signal of which a frequency is expanded by the extrapolation function;
performing Hilbert transform on the real part of the S-parameter signal of which the frequency is expanded by the extrapolation function, and obtaining a negative value thereof so as to calculate an imaginary number part of the real part of the S-parameter signal of which the frequency is expanded; and
adding the calculated real part of the S-parameter signal of which the frequency is expanded by the extrapolation function and the imaginary number part of the real part of the S-parameter signal of which the frequency is expanded, whereby a frequency-expanded S-parameter signal where causality is ensured is generated.

10. The method according to claim 1, wherein at the setting of the optimum degree and the optimum expansion frequency of the expanded S-parameter signal, an arbitrary degree 2n and an arbitrary expansion frequency fₑₓₚ at which the expanded S-parameter signal converges to zero are set as the optimum degree and the optimum expansion frequency.
